(19) United States
(12) Patent Application Publication
(10) Pub. No.: US 2013/0234149 A1
(43) Pub. Date: Sep. 12, 2013

(54) SIDEWALL TEXTURING OF LIGHT EMITTING DIODE STRUCTURES

(71) Applicants: JONATHAN D. HALDERMAN, Santa Clara, CA (US); JUAN CHACIN, San Jose, CA (US); IRVING CHYR, Fremont, CA (US)

(72) Inventors: JONATHAN D. HALDERMAN, Santa Clara, CA (US); JUAN CHACIN, San Jose, CA (US); IRVING CHYR, Fremont, CA (US)

(73) Assignee: ELECTRO SCIENTIFIC INDUSTRIES, INC., PORTLAND, OR (US)

(21) Appl. No.: 13/417,059

(22) Filed: Mar. 9, 2012

(51) Int. Cl. H01L 33/32; H01L 33/48; H01L 33/60

(52) U.S. Cl. 257/76; 438/29; 257/79; 257/E33.056; 257/E33.072

(57) ABSTRACT

A light emitting diode is made using a laser to texture the sidewalls of the bottom contact layer, without damaging a mesa. To do so, the substrate is mounted on a laser machining platform, and trenches are cut along lines through the semiconductor layer on the substrate using a first sequence of laser pulses having short pulse lengths that result in formation of textured sidewalls in the trenches, without causing recasting of the material. Then the substrate can be scribed along the lines of the trenches using a second sequence of laser pulses for singulation of die.

### BACKGROUND OF THE INVENTION

1. Field of the Invention

The technology described herein relates to manufacturing of light emitting diodes and related devices.

2. Description of Related Art

A light emitting diode LED is a multilayer semiconductor device including a diode junction in an active region that emits light when a forward bias is applied. The wavelength of the emitted light is dependent on the materials used in the active region of the device. The LED structure is normally formed on a lattice-matched, or nearly lattice-matched, substrate. For semiconductors like GaN, sapphire is a common substrate. As mentioned above, LEDs are multilayer devices. The layers for one typical LED structure include a thin nucleation layer (or buffer layer) such as GaN or AlN for sapphire substrates, used to accommodate the lattice mismatch with the substrate, an n-type AlGaN contact layer followed by an active region and top p-type contact layers. The active region typically consists of confinement layers (n-type and p-type) with either a single or multiple quantum well QW layers between them. The bottom contact layer typically is larger in area than are the overlying active region and top contact layer, to accommodate making an electrical contact on the bottom contact spaced away from the active region.

LEDs can be configured as the gain medium for laser diodes, using reflective structures on opposing sides of the LED that establish a resonant cavity for the laser function.

The efficiency of an LED can be characterized by two primary components. First, LED efficiency depends on the rate of light production per unit of input power. Second, LED efficiency depends on the ability to extract the generated light from the structure in a useable form. One known limitation in extraction efficiency of photons produced in the junction arises from total internal reflection that occurs when the angle of incidence of the photon exceeds the critical angle of the reflective interface. To limit total internal reflection, technologies have arisen to reduce the uniformity of the reflective interfaces on the LED structures.

LEDs are usually manufactured as die on a substrate. They are separated from each other by a singulation process. For singulation of GaN-based LEDs on sapphire substrates, a first common process is front side scribing (scribing through the GaN bottom contact layer) using a long (greater than 50 ns) pulse width laser. This scribing is followed by a chemical etch process called Side Wall Etch (SWE). Side Wall Etch serves to remove the recast (melted and rehardened) sapphire material created during scribing. SWE kerfs are generally smooth because the etching process preferentially follows the crystalline orientation of the sapphire. In a similar fashion, the SWE also follows the crystalline orientation of the GaN which creates a smooth sidewall on the GaN.

A second common process for LED singulation is back side scribing (the surface opposite the GaN layer is scribed). In some technologies, scribing may use either a long nanosecond (>50 ns), short nanosecond (500 ps to 50 ns) or picosecond (<500 ps) pulse width laser. After scribing, the wafer is broken on a breaking machine which propagates the notch created by scribing. The notch is propagated through the wafer as a crack that exits through the GaN. In most cases, the cracking process creates a smooth sidewall in both the sapphire and the GaN.

Also, to increase extraction efficiency, methods have been explored to texture the top surface of the semiconductor layers, including etching by inductively coupled plasma (ICP) and wet chemical etching using H₂SO₄ and H₃PO₄ solutions.

Using ICP for texturing is slow (0.5 micron per minute). See, e.g., DeVre et al. “Recent Advances in GaN Dry Etching Process Capabilities,” which can be found at: http://www.plasma-therm.com/pdfs/papers/6.%20Recent%20Advances%20in%20GaN%20Dry%20Etching%20Process%20Capabilities.pdf. Also, the tools used for ICP processes are expensive, which adds cost to the LEDs. However this slow rate of etch provides a wide process window and reduces losses due to under- or over-etching. Some of the slow rate of etch for ICP may be overcome by batch loading the wafers in the chamber—six or more wafers may be loaded at a time. To remove 10 microns of GaN from the street (create bare sapphire) on the batch of 6 wafers can require 20 to 30 minutes for a very clean sapphire surface. For a batch of 6 wafers per run this equates to 12 to 18 2″ wafers per hour for surface texturing through the ICP tool.

Wet chemical etching is difficult to control on the sidewalls, and is associated with yield losses in the LED manufacturing process. Over-etching that can occur using wet chemical etching will damage the quantum wells of the LED and degrade the performance of the device. Under-etching will not derive the full advantage associated with the etch process due to recast sapphire that is not completely removed. Additional variables such as the temperature of the etchant, contamination of the etchant, efficiency of mixing in the etchant, and the metal organic chemical vapor deposition MOCVD chamber used to grow the GaN will also change the process window for the wet etch process. An example etch time for a wet chemical etching process (e.g., dipping in HPO₄ and H₂SO₄ at 260 C) is 10 minutes for a batch of 25 2″ wafers, See U.S. Patent Application Publication No. US 2010/0314633 (Donofrio et al.). The wet chemical texturing process also requires additional processing steps including applying an SiO₂ mask before front side scribing, front side scribing, performing the wet chemical etch process, then stripping of the SiO₂ mask. These additional processes extend the wet chemical texturing time to approximately two to three hours per 25 wafer batch, which amounts to around 8 to 12 wafers per hour.

Both ICP and wet chemical etch result in a smooth sidewall profile on the GaN. This smooth sidewall has been shown to reduce the light extraction efficiency of the LED by increasing the likelihood of total internal reflection in the GaN layer.

It is desirable, therefore, to provide technologies to improve the extraction efficiency of LEDs by texturing the sidewalls of semiconductor layers of the devices, which have sufficient throughput and low enough costs for commercial applications.

### SUMMARY

Laser-based texturing of LED sidewalls, including the sidewall of bottom contact layers on LEDs, and of multilayer mesa sidewalls on LEDs, and resulting LED structures, are described.

### BRIEF DESCRIPTION OF THE DRAWINGS

FIG. 1 is a simplified diagram of a light emitting diode having a laser textured semiconductor layer.

FIG. 2 is a simplified diagram of a substrate including light emitting diode die, having laser textured semiconductor layers.

FIG. 3 is a diagram of a laser scribing machine as applied to laser texturing sidewalls of light emitting diode semiconductor layers.

FIG. 4 is a diagram of a laser scribing machine as applied to laser scribing a substrate for singulation, where the substrate includes laser textured sidewalls of light emitting diode semiconductor layers.

FIG. 5 is a diagram of a laser scribing machine as applied in an alternative process to laser scribing a substrate for singulation, where the substrate includes laser textured sidewalls of light emitting diode semiconductor layers.

FIG. 6 is an image of a substrate having a laser textured sidewall on a GaN semiconductor layer for a light emitting diode.

FIG. 7 is an image of a substrate showing damage from attempting laser texturing using a laser setting that caused large chips to be thrown off the GaN semiconductor layer for a light emitting diode.

FIG. 8 is a flow chart for a method for manufacturing a device including a light emitting diode having a laser textured semiconductor layer.

FIG. 9 is a flow chart for an alternate method for manufacturing a device including a light emitting diode having a laser textured semiconductor layer.

FIG. 10 is a simplified diagram of a substrate including light emitting diode die, without streets.

FIG. 11 is a diagram of a laser scribing machine as applied to forming trenches to separate LED mesas, while also laser texturing sidewalls of light emitting diode semiconductor layers.

FIG. 12 is a simplified side view of a light emitting diode having textured sidewalls formed without streets.

FIG. 13 is a simplified side view of a “flip-chip” light emitting diode having textured sidewalls.

FIG. 14 is a simplified diagram of a substrate with vertical light emitting diodes having textured sidewalls.

FIG. 15 is a flow chart for a method for manufacturing a device including a light emitting diode having multiple laser textured layers.

FIG. 16 is a flow chart for a method for manufacturing a vertical light emitting diode device having laser textured semiconductor layers.

### DETAILED DESCRIPTION

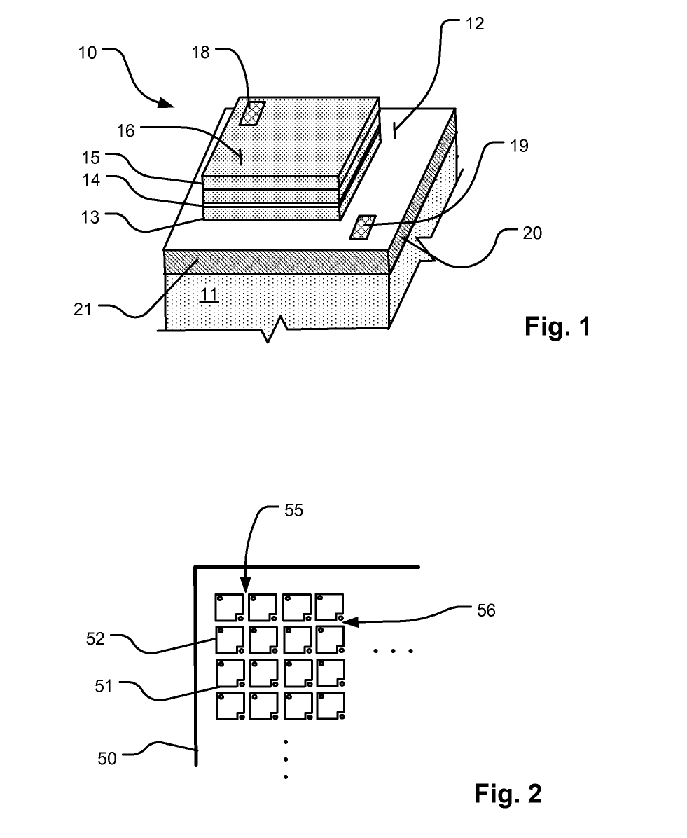

A detailed description of embodiments of the present invention is provided with reference to the FIGS. 1-16.

FIG. 1 provides a simplified illustration of a light emitting diode LED 10 manufactured as described herein. The LED includes a substrate 11 and a plurality of semiconductor layers. These layers are represented, in this example, by the semiconductor bottom contact layer 12, layers 13, 14 and 15 forming quantum wells in the active region, and a top contact layer 16. The bottom contact layer 12 is formed on the substrate 11, can have a thickness of about 10 microns, and generally less than 20 microns. As mentioned above, buffer layers can be implemented between the substrate 11 and bottom contact layer 12. Contact pads 18 and 19 are formed on the top surface of top contact layer 16 and the top surface of bottom contact layer 12. When a bias is applied to the LED structure, photons are generated in the active region, which propagate equally into all solid angles. When the photons impact an interface in the structure at above the critical angle for the interface, they are then reflected back inside the structure (total internal reflection). These internal reflections increase the odds that the photon will be absorbed within the structure before it is emitted. Thus, these internal reflections reduce the extraction efficiency. Many of the photons enter the bottom contact layer 12 before being emitted. In some embodiments, the top surface of the bottom contact layer 12 is textured. As described herein, extraction efficiency of the LED is substantially improved by laser texturing the sidewalls 20, 21 of the bottom contact layer 12. This technology has particular application for gallium nitride based LEDs formed on sapphire substrates. In such embodiments, the bottom contact layer 12 comprises a gallium nitride layer, or alloy of gallium nitride, which has been conductively doped to act as a contact layer for the LED. The technology can be applied for gallium nitride based LEDs formed on other substrates, such as silicon, silicon carbide and the like.

The LED shown in FIG. 1 is known as a horizontal or lateral LED, because the contacts for the top and bottom contact layer are on the same side of the structure and displaced laterally from one another. Other LED structures known as vertical LEDs, have contacts in or on the substrate below the bottom contact layers and contacts to the top contact layers on top, to that area of the top surface is not covered by the contact to the bottom contact layer. Vertical LEDs can also include textured sidewalls on one or more layers of the multilayer structures that form the LED. Some alternative LED structures including textured sidewalls are described below.

FIG. 2 illustrates a plurality of LED mesas (e.g. mesas 51, 52) on a substrate 50. The illustration of FIG. 2 shows the “streets” 55, 56 which provide space between the individual mesas, along which scribe lines are applied for a singulation process to form die, in a layer having for example one mesa per die. As illustrated in FIG. 2, the mesas can be shaped to make maximum use of the area available, including bottom contact vias that appear as small notches in the figure, to allow contact formation on the bottom contact layer. In other embodiments, contact patterns are formed for one or both of the top and bottom contacts, that provide a more uniform distribution of current in the mesas.

During the manufacturing process, the streets are often patterned with the bottom contact vias, to provide spacing between individual mesas. One or more of the layers, including the bottom contact layer, which make up the LED may extend across the street before a process is applied to singulate the die. For example in some embodiments, a bottom contact layer like layer 12 of FIG. 1, may be continuous across the streets before performing a process to singulate the die. The streets are defined by applying a mask on the multilayer structure, and etching through the top layers and into the bottom contact layer in the streets using ICP. Typically the bottom contact layer is not etched completely through, leaving a layer 4 to 10 microns thick in the streets. Manufacturers could etch the streets down to clean substrate, but may not, to reduce processing time in the ICP.

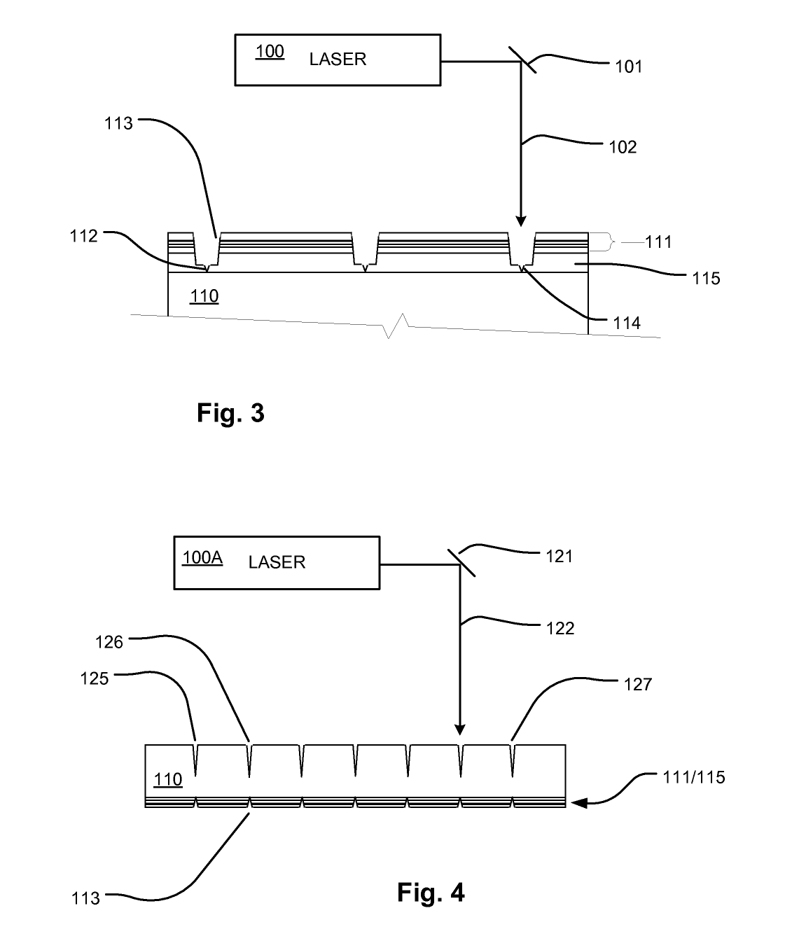

FIG. 3 illustrates a laser texturing system for texturing the sidewalls of semiconductor layers on an LED, such as the sidewall 20, 21 of the bottom contact layer 12 of FIG. 1. In this system, the substrate 110 includes a plurality of mesas including a plurality of semiconductor layers 111, separated by streets 113. The bottom contact semiconductor layer 115 is continuous across the streets in this example. To perform the process, the substrate 110 is mounted on a laser machining stage (not shown). A laser 100 is used to generate a sequence of laser pulses, which are delivered using beam delivery optics represented by element 101, on a beam line 102 as the laser machining stage is moved to cut trenches (e.g. 112, 114) within the streets (e.g. 113). In other embodiments, the stage is stationary and the laser beam is moved to form the scribe pattern, or both the stage and the beam are moved in coordination to form the scribe pattern.

The laser pulses have a pulse width, pulse intensity, and wavelength which result in textured sidewalls on the trenches. The pulse width is short enough that insufficient thermal energy is left on the substrate to cause recasting of the material due to melting and rehardening, while the pulse intensity is high enough to cause ablation or knock-off fragments or chips of the material. Recast material can absorb light emitted by the LED, and reduce its efficiency. Thus, any recast material left would need to be removed. Techniques for removing recast semiconductor material can leave smooth surfaces.

The wavelength utilized, for the sequence of pulses used for texturing the sidewall of the bottom contact semiconductor layer, depends on the materials in the semiconductor layer, and other parameters. For gallium nitride based semiconductor layers, a wavelength below about 560 nm, generally between 150 nm and 560 nm, and preferably about 532 nm or 355 nm can be used. The wavelength is chosen preferably to maximize the probability that a photon will interact with the material in a manner that causes machining. The bandgap of sapphire is approximately 9.9 eV. The bandgap of GaN is approximately 3.4 eV. The photon energy of 266 nm light is 4.7 eV, 355 nm light is 3.5 eV, 532 nm light is 2.3 eV, and 1064 nm light is 1.17 eV. 355 nm light and 266 nm light both have enough photon energy to interact with GaN (3.4 eV) using a single photon. 532 nm light and 1064 nm light require a non-linear multi-photon interaction in order to machine GaN. Nonlinear interaction is accomplished by focusing the incident beam to a small spot and by using high power pulses of laser energy. Wavelengths in this range can be produced using a neodymium doped YAG laser (1064 nm native) having second (532 nm), third (355 nm) and fourth (266 nm) harmonic generation optics. Many other types of laser systems can be utilized as well. The AccuScribe 2600, commercially available from ESI Inc., 13900 NW Science Park Drive, Portland, Oreg. 97229-5497, has demonstrated the ability to scribe through the GaN layer leaving a clean surface on the top of the sapphire substrate.

The pulse lengths applied are preferably less than 50 nanoseconds, such as 10 nanoseconds, 1 nanosecond, or 10 picoseconds. At these pulse lengths, the interaction of the pulse with the semiconductor layer can be considered essentially thermally confined, so that any thermal effects on the substrate are constrained to the material removed, and not left as thermal residues in the substrate that would accumulate and cause melting and recasting of the material. In some embodiments, pulse lengths up to 10 nanoseconds long can be suitable as long as the recasting of the semiconductor layer smoothing the texturing does not occur.

Laser texturing may be possible at a rate of speed that does not add costs to the manufacturing that outweigh the benefits achieved by the improved extraction efficiency.

It has been discovered that operating with short pulse length, and average power on the order of 0.4 to 3.0 Watts, can achieve a rate of texturing at least 120 to 300 millimeters per second. A 532 nm or a 355 nm laser can be used to texture at acceptable rates through a 10 micron thick layer of GaN, by applying a sequence of overlapping pulses, having a pulse repetition rate of 500 to 1000 kHz, a spot size of 0.5 to 3 microns, at an average power of 0.5 to 1 Watts. Throughtput for this system can be understood with reference to the smallest (or one of the smallest) wafer currently in general use at about 50 mm in diameter. A standard die size for LCD backlights is 10 mil×23 mil (250 um×584 um). At 180 mm/sec the throughput for scribing this type of small wafer is 12-18 wafers per hour (WPH). Deposition of the LED layers using a MOCVD chamber can have an average throughput is 48 wafers in 6-9 hours or 5-8 wafers per hour. Thus, approximately 1 scribing system per 3 MOCVD chambers can be used in the factory without sacrificing throughput. Slower techniques would require significantly more capital expenditures, and drive up the costs of manufacturing significantly. Thus, it is considered important for a texturing process as described herein to achieve a texturing rate of at least 120 millimeters per second, and preferably 180 millimeters per second, or higher.

FIG. 4 illustrates a laser scribing system for scribing a substrate that includes a plurality of LED die for the purposes of singulation. In the system, the substrate 110 is mounted with the semiconductor layers 111/115 facedown on a laser machining stage (not shown) for scribing the back side of the substrate. A laser 100A is utilized, which could be the same laser as used for the texturing process of FIG. 3, or a different laser specially adapted for the substrate scribing for singulation. The laser generates a sequence of laser pulses which are delivered using beam delivery optics represented by the element 121, on a beam line 122 to the substrate. Kerfs (e.g. 125, 126, 127) are formed in the substrate in alignment with the streets (e.g. kerf 126 is aligned with street 113). Not shown in FIG. 4 are the textured sidewall trenches made as described with reference to FIG. 3. The kerfs can comprise trenches, or melted seams, or combinations of trenches and seams. The kerfs provide singulation lines for the individual die on the substrate. Typically, for example, the substrate is placed on a flexible tape. After scribing, the substrate is cracked along the scribe lines. Then the flexible tape is stretched to separate the die so that they can be picked up by pick-and-place robots. It can be seen from FIG. 4 that the laser scribing for the purposes of singulation is a separate step from that applied for texturing of the sidewalls of the semiconductor layer. Other scribing processes can be used as well for singulation of the die, such as sawing on the front or back side of the substrate.

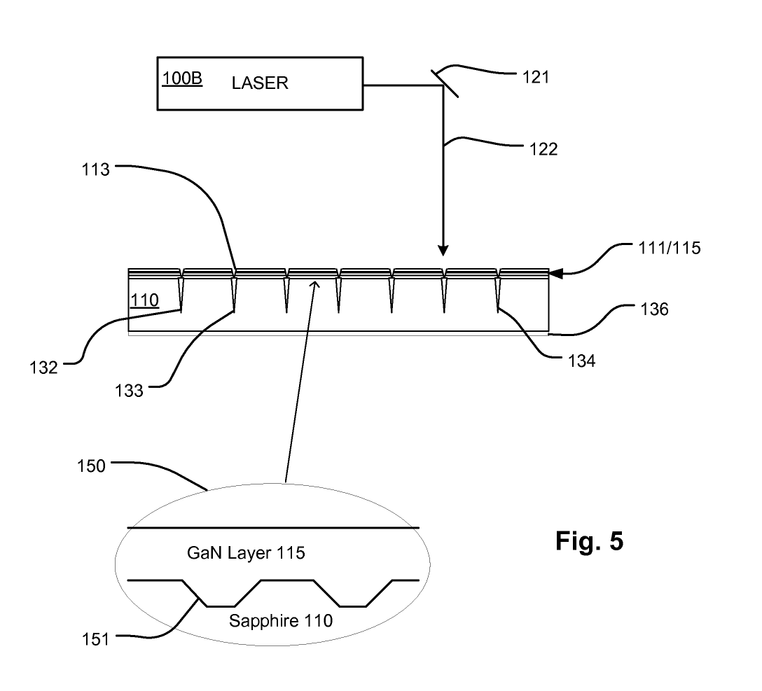

FIG. 5 illustrates a system arranged for an alternative process for laser scribing for singulation, and the use of a mirror layer on the back side, along with a patterned sapphire substrate. In FIG. 5, the system describes a substrate that includes a plurality of LED mesas for the purposes of singulation, where the substrate is mounted face up. The substrate in this example includes a mirror layer 136 on the back side, which can improve emission efficiency. Thus, substrate 110 is mounted with the semiconductor layers 111/115 on top for scribing the top side of the substrate. The laser system 100B delivers a sequence of pulses through beam delivery optics (element 121) on beam line 122 to form scribe lines within the streets (e.g. street 113) on the substrate. As illustrated, the scribe lines (e.g. kerfs 132, 133, 134) align with the trenches formed for laser texturing. In this embodiment, it is important that the laser pulses used for singulation not impact or cause melting on the sidewalls of the trenches in the semiconductor layer. Singulation scribing can be accomplished using short pulse lengths, (less than 50 ns) like that used for texturing, so as to avoid melting and blowing of large chips from the textured sidewall. It is preferred in embodiments including reflective mirror layer 136 (reflective of light emitted by the LED) to perform top side scribing in order to maximize the area covered by the mirror layer 136 on the finished die.

Also, as illustrated, in callout region 150, the substrate can be a patterned sapphire substrate PSS. See, e.g., Huang et al., “Effect of Patterned Sapphire Substrate Shape on Light Output Power of GaN-Based LEDs,” IEEE PHOTONICS TECHNOLOGY LETTERS, Vol. 23, No. 14, Jul. 15, 2011, pages 944-946. In a PSS substrate, the sapphire has a pattern of cones or hexagons on the surface 151. In other examples, the substrate can include patterns other than those representative of PSS technology. Also, the substrate can include a nano-patterned, randomly roughened, or textured surface, on which the bottom contact semiconductor layer is placed. This patterning or roughening improves extraction efficiency, and is widely used. In a method for texturing and singulation on a patterned or roughened substrate, the singulation scribing and the texturing can be performed in two passes, where the texturing forms trenches that expose the patterned or roughened surface at least partially. During the second pass for singulation scribing, the pulses can be more efficiently used for scribing in this manner without interacting with the textured sidewall of the semiconductor layer in a manner that can damage the mesas or contact areas on the die.

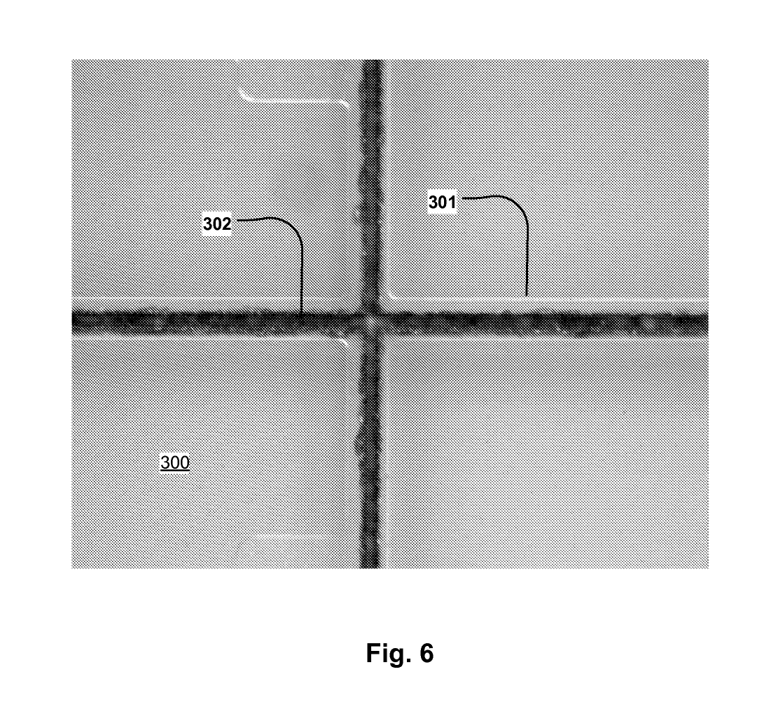

FIG. 6 is an image showing a substrate 300 having an LED mesa formed thereon, used in formation of an LED. A mesa in the image has a perimeter 301 adjacent a street. A trench 302 is formed in the street. The sidewalls on the trench 302 are textured, having an average surface roughness Ra on the order of a micron, including for example an average roughness greater than about 0.3 microns. An average street width can be 25 microns to 35 microns in some LED structures. Kerf widths of 9 microns or less are desired in such embodiments. If the pieces of material removed during the texturing process are too large they will hit the mesas (active LED structures). Chips greater than 8 microns ((25−9)/2) would be unacceptable in these embodiments. If the ideal surface is the edge of a 9 microns kerf (straight line) and the chip size ejected during the process is always less than 4 μm, the Rt value will be +4−(−4)=8 microns. The Ra can be approximated to be on the order of ⅙ the Rt value (range ˜6 sigma), so an acceptable Ra is estimated to be approximately 1.4 microns. Ra is the arithmetic average of the absolute values of collected roughness data points used to measure the roughness, and Rt is the range of the collected roughness data points.

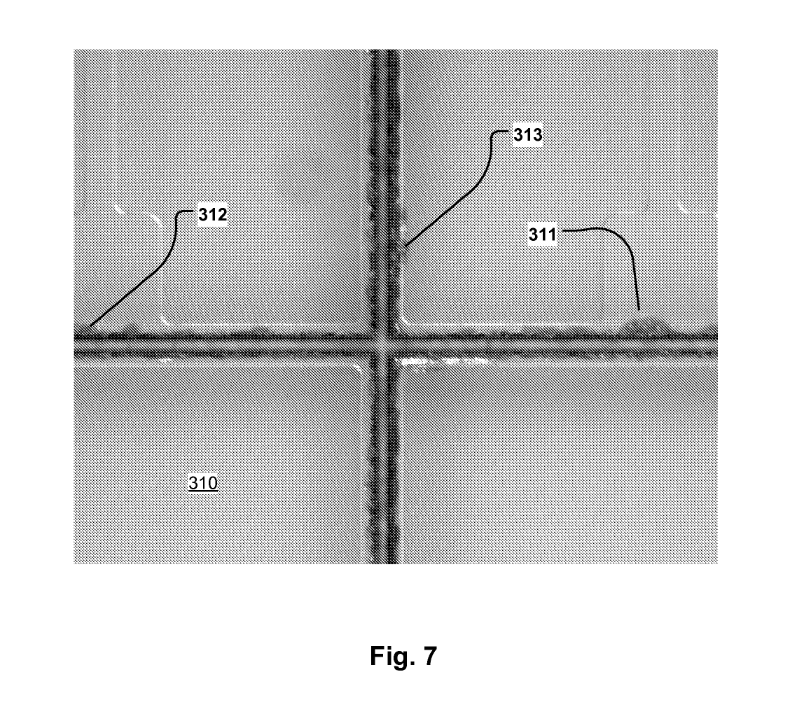

FIG. 7 is an image showing a substrate 310, like that of FIG. 6, having LED mesas formed thereon, used in formation of an LED. A sequence of laser pulses has been applied in the streets using power densities too high for successful texturing, because large chips have been blown off that damage the mesas. The damage can be seen at reference numbers 311, 312, 313 in the Figure. Such damage places a limit on the roughness of the texturing. Thus, embodiments of the texturing process can cause a sidewall average roughness Ra greater than about 0.3 microns, and limited on the high end by a roughness that damages the mesas. This outer limit for a 70 micron street, as described above, can be on the order of Ra equal 4 microns.

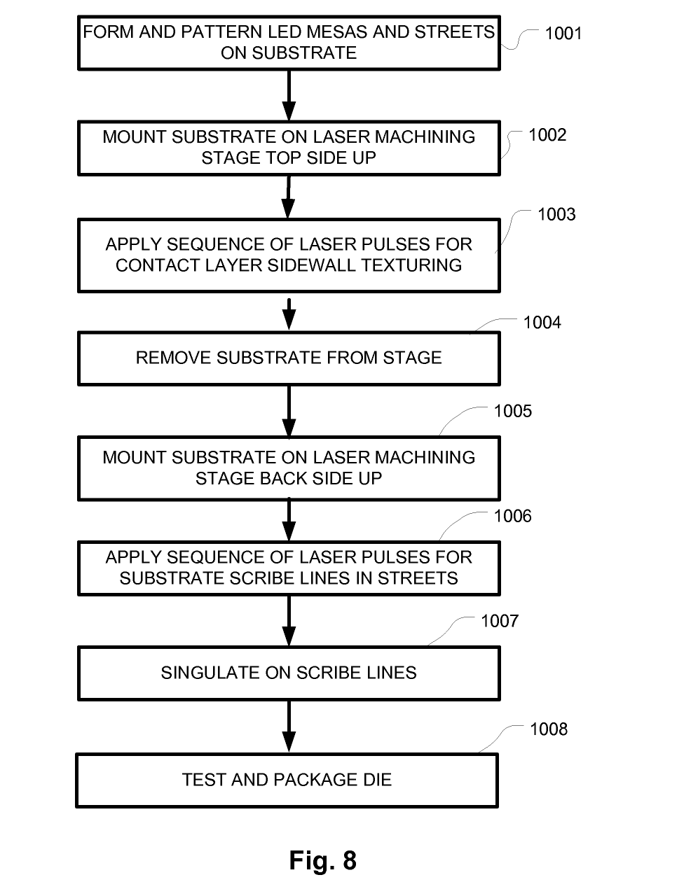

FIG. 8 illustrates a method for manufacturing LEDs having textured sidewalls as described herein. First, LED mesas and streets are formed and patterned on a substrate, according to processes which leave multilayer semiconductor structures arranged as mesas in a pattern, with streets between the individual mesas (1001). The substrate having an array of LED mesas formed thereon, is mounted on a laser machining stage with the top side up (i.e. the side with the array of LED mesas facing toward the laser) (1002). A sequence of laser pulses is applied to cause sidewall texturing on one of the semiconductor layers in the multilayer structure (1003). The textured layer in representative LED structures is the bottom contact layer which can extend to or across the street between the mesas in some embodiments. The sequence of pulses can be applied in a scribe pattern which traverses the streets in a pulse repetition rate sufficient to cause overlapping of the successive pulses as the beam or stage is moved.

In some embodiments, the pulses can be applied in a pattern by which a pulse on a given scribe line is delivered to a first point, and a second pulse is delivered to a second point spaced away from the first so that residual heat from the first and second pulses is not accumulated. Then, the laser pattern can include a third pulse adjacent to or overlapping the first point, and followed by a fourth pulse adjacent to or overlapping the second point, and so on to complete the texturing procedure. This or other patterns can be applied to avoid accumulating sufficient heat to cause reflow of the semiconductor material during the texturing process. After delivering the sequence of pulses for sidewall texturing, the substrate is removed from the stage (1004). Next, the substrate is mounted on a laser machining stage with the back side up (1005). This may be the same stage or a different stage than that used for texturing. Then, a sequence of laser pulses is applied to form scribe lines in the streets used for singulating die that include at least one mesa each (1006). After scribing for singulation, the die are singulated (1007). Finally, the singulated die are tested and packaged for delivery to customers (1008). Other singulation technologies may be applied as well, including processes that include mechanical scribing.

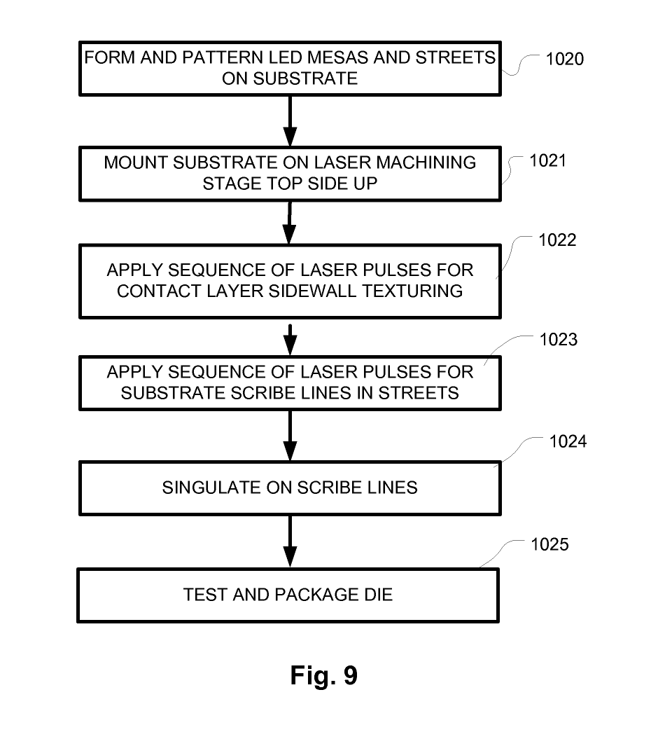

FIG. 9 illustrates one alternative process for manufacturing LEDs having textured sidewalls. According to this process, the LED mesas and streets are formed and patterned on a substrate (1020). The substrate is mounted on a laser machining stage, top side up (1021). Next, a sequence of laser pulses for contact layer sidewall texturing is applied as described above (1022). After sidewall texturing, or in alternative systems before sidewall texturing, a sequence of laser pulses for forming substrate scribe lines in the streets between the die is applied while the substrate remains on the same laser machining stage (1023). The sequence of pulses used for singulation scribing can be delivered by the same laser as, or a different laser than, that used for sidewall texturing. After scribing and texturing, individual die are singulated along the scribe lines (1024). Finally, the die are tested and packaged (1025). The order of steps illustrated in FIGS. 8 and 9 can be rearranged as suits a particular manufacturing system.

In some embodiments, the mesas and streets are formed and patterned on the substrate in one manufacturing line, and then delivered to a different manufacturing line for the purposes of sidewall texturing and singulation. Alternatively, the sidewall texturing and the singulation could be performed in separate locations. Likewise, the mounting and testing of the die can be carried out in the same or different manufacturing locations as that used for texturing and singulation.

In the examples described here, the sidewall texturing is applied in a rectangular pattern to the contact layer in the streets. In other embodiments, the sidewall texturing could be applied in other places on the die, including in patterns that are not simple rectangles.

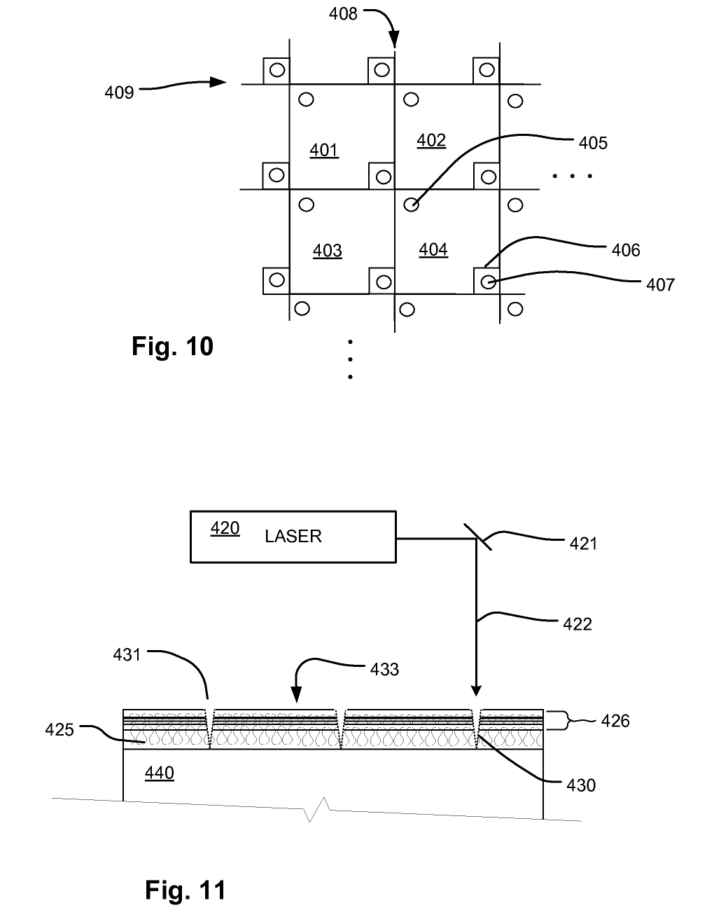

Laser sidewall texturing can also be applied in embodiments that do not include streets separating mesas on the substrate. This can be understood with reference to FIGS. 10 and 11. FIG. 10 illustrates a portion of a substrate including outlines 408, 409 of a plurality of individual die 401, 402, 403, 404 without patterned streets. The outlines 408, 409 are shown for the purposes of description, but need not appear as markings or patterns on a layout view at this stage of the manufacturing process. Each of the individual die includes a top contact (e.g. 405), a bottom contact (e.g. 407), and a bottom contact via (e.g. 406). As mentioned above, the contact patterns can be much more complex than shown in this example. A sequence of laser pulses can be applied to form textured sidewall trenches, separating the individual mesas on each of the die 401, 402, 403, 404 extending through the multiple layers which form the LED mesas, down to a substrate.

FIG. 11 illustrates a configuration of a manufacturing system applying laser sidewall texturing for forming individual mesas on a substrate. In this example, the substrate 440 includes a bottom contact layer 425, and multilayer structure 426 that includes a top contact layer, and active layers of the LED. The laser 420 and beam delivery optics 421 are configured to deliver a sequence of laser pulses on the line 422 in order to cut textured sidewall trenches, such as textured sidewall trench 430 and textured sidewall trench 431, through the multilayer structure 426 and the bottom contact layer 425 to expose or at least partially expose the substrate 440. The textured sidewalls exposed in FIG. 11 correspond for example to a sidewall along line 409 on the die 401, 402, where there is no contact via contacting the edge of the mesa. As result of textured sidewall trenches, individual mesas (e.g. mesa 433) are patterned on the substrate. A scribing process can be applied, as described above, using a different sequence of laser pulses or a different process to singulate the die. In embodiments where streets are eliminated, and a patterned etch, using for example ICP, is applied only to define the contact vias, the effective device area can be increased. Particularly using a textured sidewall trench formed using a laser as described herein, can perform the dual functions of providing textured sidewalls on multiple layers of the LED stack, and of separating the mesas with structures that are narrower than streets formed in conventional LED processes.

For example, assuming a device the size that is about 254 microns by 584.2 microns, with 25 micron streets, mesas of the LEDs could be defined that cover about 229 microns by 559 microns which corresponds to an area of about 0.128 mm². However, using a 10 microns wide textured sidewall trench, the area of the mesa can increase to about 244 microns by 574 microns, which corresponds to an area of about 0.140 mm². Accordingly, in this example, an increase in LED area of about 9% is achieved by eliminating the streets, and replacing them with textured sidewall trenches. The additional LED area, combined with the improved efficiency achieved by sidewall texturing of one or more of the multiple layers of the mesas, yields a device that can provide significantly improved brightness.

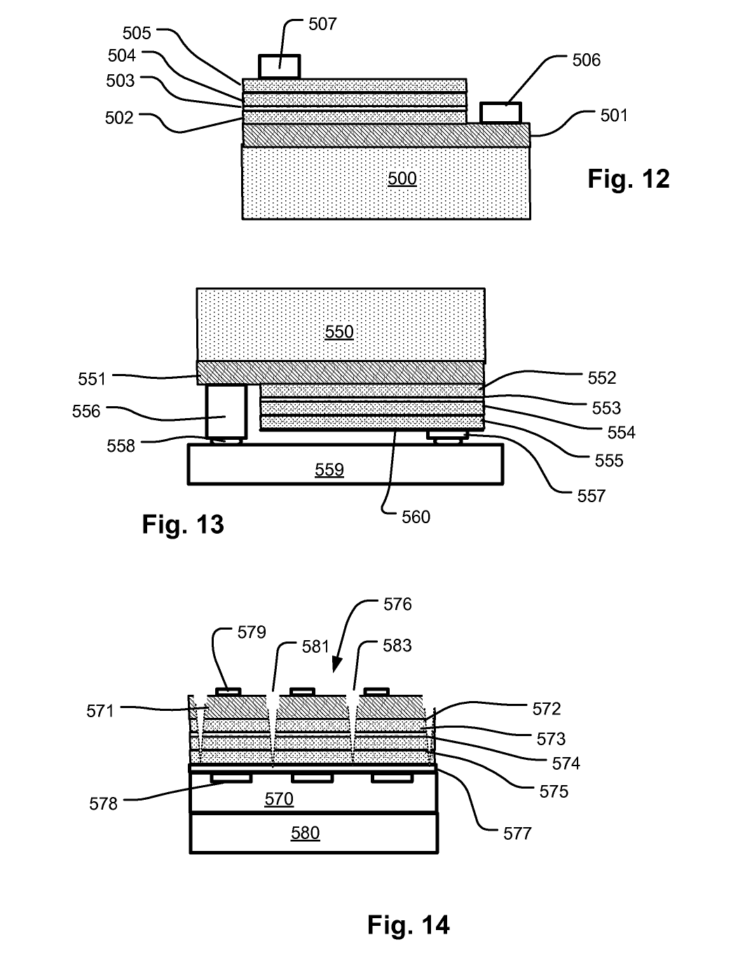

FIG. 12 through FIG. 14 illustrate alternative device structures that can be made using a laser sidewall texturing process as described herein. FIG. 12 shows a LED on a substrate 500 including a bottom contact layer 501, and a mesa including multiple active layers 502, 503, 504 and a top contact layer 505. A contact pad 506 is placed in a contact via on the bottom contact layer 501. A contact pad 507 is placed on the top contact layer 505. In this example, and in contrast to the device shown in FIG. 1, each layer in the multilayer structure that defines the mesa, including the bottom contact layer 501 has been processed using laser-based sidewall texturing. In other embodiments, one or more of the layers in the multilayer structure may be textured in addition to the bottom contact layer 501, while one or more of the layers may be formed without exposure to the laser-based sidewall texturing.

FIG. 13 shows another representative LED device. In this example, a “flip-chip” structure is shown where the substrate 550, which can comprise sapphire for example, along with the LED structure have been turned over and bonded to a receptor substrate 559. As illustrated, the bottom contact layer 551 is in contact with the substrate 550. A mesa including multiple active layers 552, 553, 554 and a top contact layer 555 are formed on the bottom contact layer 551. A contact plug 556 is placed in a contact via on the bottom contact layer 551. A contact pad 557 is placed on the top contact layer 555. The contact plug 556 and the contact pad 557 are soldered (e.g. 558) or otherwise bonded to corresponding contacts on a receptor substrate 559, which can comprise an integrated circuit or a printed circuit board providing circuitry for powering and controlling the LED device. In this example, the reflective layer 560 can be formed on the surface of the top contact layer 555 so that the emitted light is redirected out through the substrate 550. As with the example of FIG. 12, and in contrast to the device shown in FIG. 1, each layer in the multilayer structure that defines the mesa, including the bottom contact layer 551 has been processed using laser-based sidewall texturing. In other embodiments, one or more of the layers in the multilayer structure maybe textured in addition to the bottom contact layer 551, while one or more of the layers may be formed without exposure to the laser-based sidewall texturing.

FIG. 14 shows yet another representative LED device, including an array of vertical LEDs on a receptor substrate 580. The vertical LED array structure can be formed by a procedure which includes first forming the layers of material used to define LEDs on a substrate, followed by an adhesive layer and reflectors arranged over individual LED devices. A bonding material can be applied over the adhesive and reflector, and then this intermediate structure can be bonded to a receptor wafer. The original wafer is then lifted off and mesa etching applied. According to the present invention the mesa etching can be accomplished by forming textured sidewall trenches (581, 583) using a laser. The structure illustrated in FIG. 14 includes a receptor substrate 580 on a bonding layer 570. Individual reflectors (e.g. 578) underlie the LED mesas (e.g. 576). The semiconductor layers that make up the LED including bottom contact layer 571, the multilayer structure including active region layers 572, 573, 574 and a top contact layer 575 are formed in contact with the reflectors (e.g. 578) via adhesive layer 577 in this example. A top contact pad (e.g. 579) is formed on each mesa that is separated by textured sidewall trenches 581, 583. Again, in this example all of the layers of the LED stack are laser textured. As mentioned above, in other embodiments, one or more of the layers could be left untextured. Rather than maintaining an array of vertical LEDs on a single substrate, in some embodiments the structure of FIG. 14 could be exposed to a traditional process to singulate the individual LEDs.

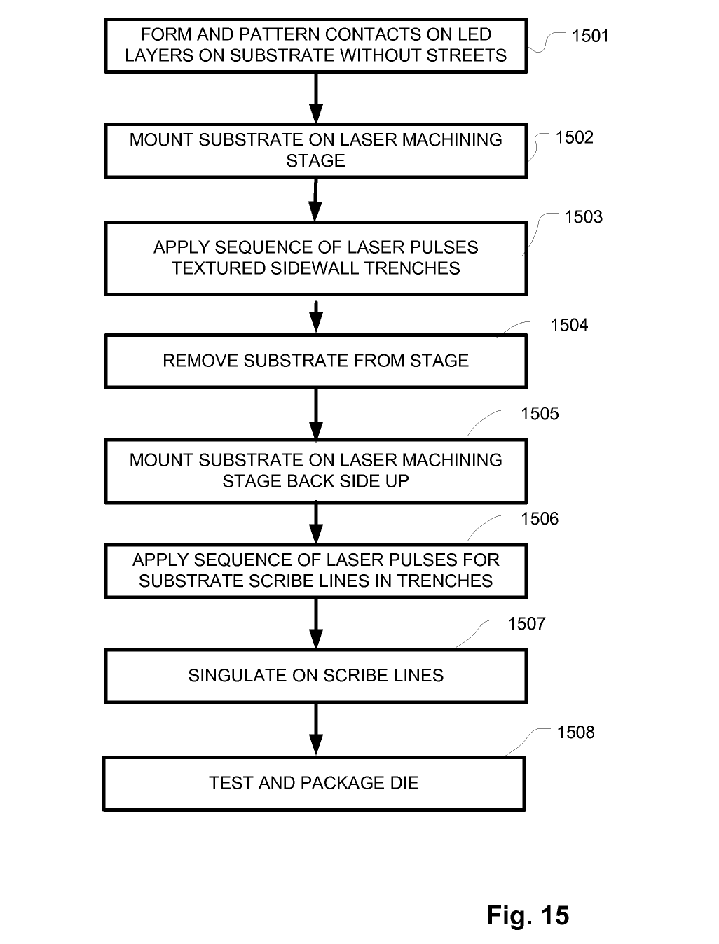

FIG. 15 is a simplified flowchart of a manufacturing process applying laser-based sidewall texturing to substrates without streets. In this example, the process includes forming and patterning contacts on the multilayer LED structures without streets (1501). The substrate without streets is mounted on a laser machining stage (1502). Next, a sequence of laser pulses is applied to form textured sidewall trenches, which accomplishes the dual goals of mesa separation and sidewall texturing (1503). Next, in this example the substrate is removed from the stage (1504) and then mounted on a laser machining stage (1505). Then, a sequence of laser pulses is applied to form substrate scribe lines within the textured sidewall trenches (1506). In other embodiments, the laser machining used for creating scribe lines for singulation of the die can be performed on the same stage as that used for forming textured sidewall trenches. After forming the scribe lines, the individual die are singulated (1507). Finally, the die are tested and packaged (1508).

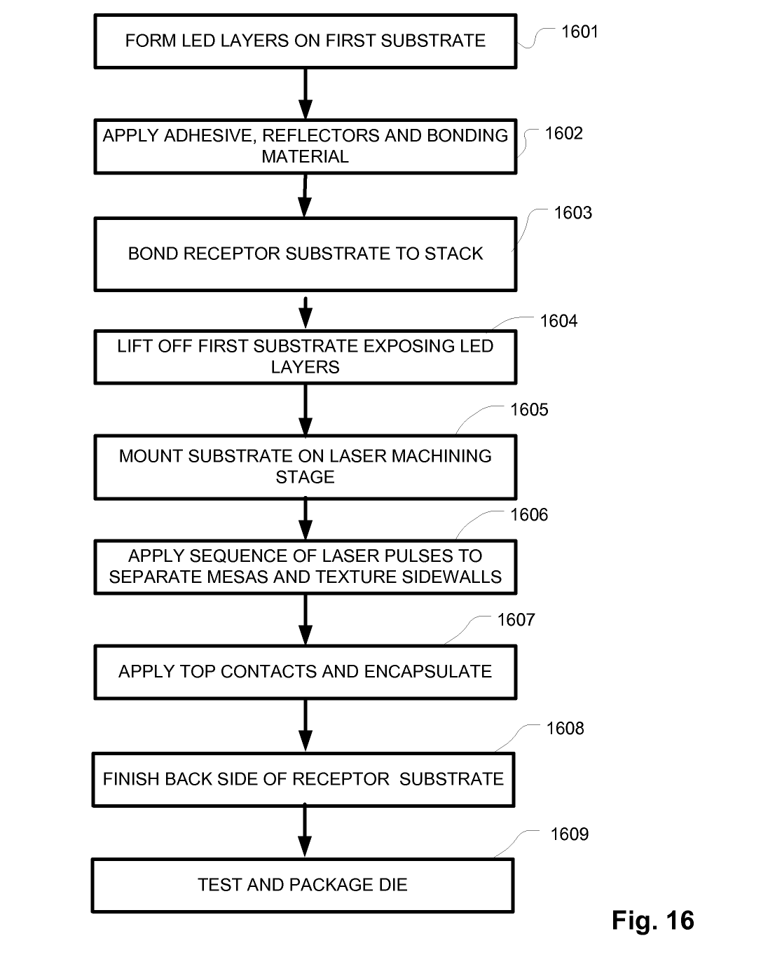

FIG. 16 illustrates yet another example manufacturing process applying laser-based sidewall texturing to substrates, which are arranged for formation of vertical LEDs on receptor substrates. In the sequence, the process includes forming multiple semiconductor layers used for LED formation on a first substrate (1601). The first substrate can be singulated, so that it includes a single LED per die, or an array of LEDs per die. Alternatively, the process can proceed without singulation of the first substrate. Next, an adhesive, reflectors, and bonding material are applied to only the top layer of the multilayer structure (1602), forming a preliminary assembly that includes the first substrate with the stack of LED layers formed thereon. Then, the preliminary assembly is bonded to a receptor substrate (1603), so that the top contact layer lies on the bonding material. Then, the first substrate is lifted off exposing the stack of LED layers (1604). The receptor substrate, including the LED stack, is mounted on a laser machining stage (1605). Then, a sequence of laser pulses is applied to separate mesas and texture the sidewalls of the mesas (1606). Top contacts are applied on individual mesas, and the structure is encapsulated as appropriate (1607). Next, the backside of the receptor substrate is finished, such as by reducing its thickness, and applying patterned metal lines (1608). Finally, the die are tested and packaged (1609).

Laser based texturing of the bottom contact layer sidewall only, and of the sidewalls on multiple layers of the LED mesas, has several benefits. The laser will not undercut the mesa and can be localized to a narrow trench 5 to 10 microns wide in the center of the street between mesas. In addition, the laser based process is very fast and can process on the order of eighteen 2″ wafers per hour depending on the die size. The repeatability of the laser based scribing process is very good, meaning that the yield losses and variability of output from the laser scribing system should be lower than the losses associated with wet etching. In addition, the surface texture remaining after laser based texturing reduces total internal reflection and improves light extraction efficiency of the LED.

Also, the formation of textured sidewall trenches using laser processes described herein can provide the dual purposes of texturing the side walls of the layers of the LED, along with separation mesas. This can eliminate the requirement for laying out streets on the substrate that consume area and reduce the effective brightness of the devices made.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A method for manufacturing a light emitting diode LED, comprising:
mounting a substrate on a laser machining platform, the substrate including a plurality of mesas separated by streets, mesas in the plurality including corresponding multilayer structures including a semiconductor layer; and
texturing sidewalls in the semiconductor layer using a sequence of laser pulses.

2. The method of claim 1, wherein said texturing includes causing removal of chips of material of the semiconductor layer without leaving residual recast material.

3. The method of claim 1, wherein the laser pulses have a pulse duration less than 50 nanoseconds.

4. The method of claim 1, wherein said texturing includes cutting a trench in the semiconductor layer in or along at least one of the streets, said sidewalls being sidewalls of the trench.

5. The method of claim 1, wherein said texturing results in the sidewalls having an average roughness Ra greater than 0.3 microns without damage to the mesas.

6. The method of claim 1, wherein said texturing results in the sidewalls having an average roughness Ra greater than 0.3 microns and less than 4 microns.

7. The method of claim 1, wherein the semiconductor layer comprises a GaN bottom contact layer of the LED.

8. The method of claim 1, wherein the semiconductor layer comprises GaN, having a thickness at the sidewalls of 20 microns or less.

9. The method of claim 1, wherein the substrate includes a reflective layer on a side opposite the multilayer structures, which is reflective for light emitted by the LED.

10. The method of claim 1, wherein the substrate has a patterned surface, and the semiconductor layer is on the patterned surface, and wherein said texturing includes cutting a textured sidewall trench that exposes the substrate within the trench, and scribing the substrate for singulation of die including the mesas, using a different sequence of laser pulses delivered to the exposed substrate within the trench.

11. The method of claim 1, wherein the substrate has a nano-patterned, randomly roughened, or textured surface, and the semiconductor layer is on the roughened surface, and wherein said texturing includes cutting a textured sidewall trench that exposes the substrate within the trench, and scribing the substrate for singulation of die including the mesas, using a different sequence of laser pulses delivered to the exposed substrate within the trench.

12. The method of claim 1, wherein the sequence of laser pulses has an average power sufficient to texture the sidewall at a rate exceeding 180 mm/second.

13. The method of claim 1, wherein the semiconductor layer comprises GaN, and the substrate comprises sapphire.

14. The method of claim 1, including scribing the substrate for singulation of die including the mesas, using a different sequence of laser pulses, before or after texturing sidewalls in the semiconductor layer.

15. The method of claim 1, wherein the multilayer structure includes said semiconductor layer, an active region including one or more layers, and a top contact layer.

16. A light emitting diode manufactured according to the method of claim 1.

17. A method for manufacturing a light emitting diode LED, comprising:
mounting a substrate on a laser machining platform, the substrate including a plurality of mesas separated by streets, mesas in the plurality including corresponding multilayer structures including a semiconductor layer;
forming textured sidewall trenches along lines through the semiconductor layer on the substrate using a first sequence of laser pulses; and
scribing the substrate along the lines of the trenches for singulation of die including the mesas.

18. The method of claim 17, wherein the substrate includes a reflective layer on a side opposite the multilayer structures, which is reflective for light emitted by the LED.

19. The method of claim 17, wherein the substrate has a patterned surface, and the semiconductor layer is on the patterned surface, and wherein said forming a trench includes cutting a trench that exposes the substrate within the trench, and said scribing for singulation forms a scribe line in the trench on the exposed substrate.

20. The method of claim 17, wherein the substrate has a nano-patterned, randomly roughened, or textured surface, and the semiconductor layer is on the roughened or textured surface, and wherein said forming a trench includes cutting a trench that exposes the substrate within the trench, and said scribing for singulation forms a scribe line in the trench on the exposed substrate.

21. The method of claim 17, wherein said texturing includes causing removal of chips of material of the semiconductor layer without leaving residual recast material.

22. The method of claim 17, wherein the laser pulses have a pulse duration less than 50 nanoseconds.

23. The method of claim 17, wherein said textured sidewalls have an average roughness Ra greater than 0.3 microns without damage to the mesas.

24. The method of claim 17, wherein said textured sidewalls have an average roughness Ra greater than 0.3 microns and less than 4 microns.

25. The method of claim 17, wherein the semiconductor layer comprises a GaN bottom contact layer of the light emitting diode.

26. The method of claim 17, wherein the semiconductor layer comprises GaN, having a thickness at the sidewalls of 20 microns or less.

27. The method of claim 17, wherein the sequence of laser pulses has an average power sufficient to texture the sidewall at rate exceeding 120 mm/second.

28. The method of claim 17, wherein the semiconductor layer comprises GaN, and the substrate comprises sapphire.

29. A light emitting diode manufactured according to the method of claim 17.

30. A method for manufacturing a light emitting diode LED, comprising:
mounting a substrate on a laser machining platform, the substrate including a plurality of layers of materials, including a bottom contact layer, one or more active layers, and a top contact layer;
forming textured sidewall trenches through the plurality of layers on the substrate using a first sequence of laser pulses dividing the plurality of layers into a plurality of mesas; and
scribing the substrate along the trenches for singulation of die including the mesas using a scribing process different than said first sequence of laser pulses.

31. The method of claim 30, wherein the substrate includes vias through the plurality of layers exposing contact areas on the bottom contact layer.

32. The method of claim 30, including a reflective layer between the plurality of mesas and the substrate, which is reflective for light emitted by the LED.

33. The method of claim 30, wherein the LED is a vertical LED, having a contact to an individual mesa below the mesa in the substrate, and a contact to the given mesa on top of the mesa.

34. The method of claim 30, wherein the scribing process includes applying a second sequence of laser pulses through the trenches into the substrate.

35. The method of claim 30, wherein the scribing process includes applying a second sequence of laser pulses along scribe lines on a side of the substrate opposite the mesas.

36. A light emitting diode manufactured according to the method of claim 30.

37. A light emitting diode LED comprising:
a substrate;
a bottom contact layer on the substrate;
a mesa including a multilayer structure on the bottom contact layer and including a top contact layer; and
the bottom contact layer having sidewalls with an average roughness Ra greater than 0.3 microns, and less that 4 microns.

38. The light emitting diode of claim 37, wherein the substrate comprises sapphire and the bottom contact layer comprises GaN.

39. The light emitting diode of claim 37, wherein the substrate comprises a patterned sapphire substrate and the bottom contact layer comprises GaN.

40. The light emitting diode of claim 37, wherein the substrate comprises a reflective layer on a side opposite the mesa, which is reflective for light emitted by the LED.

41. The light emitting diode of claim 37, wherein
a plurality of layers in the multilayer structure have an average roughness Ra greater than 0.3 microns, and less that 4 microns.
